(19) United States
(12) Patent Application Publication
(10) Pub. No.: US 2026/0223354 A1
(43) Pub. Date: Jul. 30, 2026

(54) SEMICONDUCTOR MEMORY DEVICE

(71) Applicant: Samsung Electronics Co., Ltd., Suwon-si (KR)

(72) Inventors: Taegyu KANG, Suwon-si (KR); Jinwoo HAN, Suwon-si (KR)

(21) Appl. No.: 19/283,655

(22) Filed: Jul. 29, 2025

(30) Foreign Application Priority Data
Jan. 24, 2025 (KR) 10-2025-0011056

(51) Int. Cl. H10B 12/00

(52) U.S. Cl. CPC H10B 12/30; H10B 12/05

(57) ABSTRACT

A semiconductor memory device includes a substrate, semiconductor patterns stacked on the substrate in a first direction, word lines surrounding the semiconductor patterns, respectively, a bit line on a first side of each semiconductor pattern, and a capacitor structure on a second side of each semiconductor pattern. Each semiconductor pattern includes a first source/drain region adjacent to the bit line, a second source/drain region adjacent to the capacitor structure, and a channel region between the first source/drain region and the second source/drain region. The first source/drain region includes a first portion extending in the third direction from the channel region, and a second portion surrounding the first portion.

### CROSS-REFERENCE TO RELATED APPLICATION

This application claims priority to Korean Patent Application No. 10-2025-0011056, filed in the Korean Intellectual Property Office on January 24, 2025, the entire contents of which are hereby incorporated by reference.

### TECHNICAL FIELD

The present disclosure relates to a semiconductor memory device.

### BACKGROUND

As used herein, the semiconductor device refers to a core component used to control or amplify electric signals in electronic apparatuses, and various kinds of semiconductor devices may be manufactured. For example, a semiconductor memory device is mainly used to store and retrieve data. A semiconductor memory device is an essential component of electronic apparatuses such as computers, communication equipment, and consumer electronic products.

In accordance with the development of industry, there is an increasing demand for performance and functionality of electronic apparatuses. Accordingly, high performance of semiconductor memory devices is essential, and the degree of integration of semiconductor memory devices continues to increase to meet this demand. During such development, new transistor structures, such as a transistor having a vertical channel and a vertical stack transistor, have been proposed.

The above information is provided merely to facilitate understanding of the background of the present disclosure and may include information that does not constitute prior art.

### DESCRIPTION

### PROBLEM TO BE SOLVED

The present disclosure is directed to providing a semiconductor memory device having improved electrical characteristics and/or reliability.

### SUMMARY

According to an aspect of the present disclosure, a semiconductor memory device includes a substrate, a plurality of semiconductor patterns stacked on the substrate and being spaced apart from each other in a first direction perpendicular to an upper surface of the substrate, a plurality of word lines surrounding the plurality of semiconductor patterns, respectively, and extending lengthwise in a second direction parallel to the upper surface of the substrate and intersecting the first direction, a bit line on a first side of each semiconductor pattern of the plurality of semiconductor patterns and extending lengthwise in the first direction, and a capacitor structure on a second side of each semiconductor pattern of the plurality of semiconductor patterns, the second side being opposite to the first side in a third direction parallel to the upper surface of the substrate and intersecting the first direction and the second direction, and each semiconductor pattern of the plurality of semiconductor patterns extending lengthwise in the third direction. Each semiconductor pattern of the plurality of semiconductor patterns includes a first source/drain region adjacent to the bit line, a second source/drain region adjacent to the capacitor structure, and a channel region between the first source/drain region and the second source/drain region. The first source/drain region, the channel region, and the second source/drain region are arranged in the third direction. The first source/drain region includes a first portion extending in the third direction from the channel region, and a second portion surrounding the first portion.

According to an aspect of the present disclosure, a semiconductor memory device includes a substrate, a plurality of semiconductor patterns stacked on the substrate in a first direction perpendicular to an upper surface of the substrate, a plurality of word lines surrounding the plurality of semiconductor patterns, respectively, and extending in a second direction parallel to the upper surface of the substrate and intersecting the first direction, a bit line on a first side of each semiconductor pattern of the plurality of semiconductor patterns and extending lengthwise in the first direction, and a capacitor structure on a second side of each semiconductor pattern of the plurality of semiconductor patterns, the second side being opposite to the first side in a third direction parallel to the upper surface of the substrate and intersecting the first direction and the second direction, and each semiconductor pattern of the plurality of semiconductor patterns extending lengthwise in the third direction. Each semiconductor pattern of the plurality of semiconductor patterns includes a first source/drain region adjacent to the bit line, a second source/drain region adjacent to the capacitor structure, and a channel region between the first source/drain region and the second source/drain region. A material of the first source/drain region is different from a material of each of the channel region and the second source/drain region.

According to an aspect of the present disclosure, a semiconductor memory device includes a substrate, a plurality of semiconductor patterns stacked on the substrate in a first direction perpendicular to an upper surface of the substrate, a plurality of word lines surrounding the plurality of semiconductor patterns, respectively, and extending lengthwise in a second direction parallel to the upper surface of the substrate and intersecting the first direction, an interlayer insulating layer interposed between two adjacent word lines of the plurality of word lines, a bit line on a first side of each semiconductor pattern of the plurality of semiconductor patterns and extending lengthwise in the first direction, a capacitor structure on a second side of each semiconductor pattern of the plurality of semiconductor patterns, the second side being opposite to the first side in a third direction parallel to the upper surface of the substrate and intersecting the first direction and the second direction, wherein each semiconductor pattern of the plurality of semiconductor patterns comprises a first source/drain region adjacent to the bit line, a second source/drain region adjacent to the capacitor structure, and a channel region between the first source/drain region and the second source/drain region, and wherein the first source/drain region extends in the third direction from the channel region, and a hole collection layer configured to collect holes in a corresponding semiconductor pattern of the plurality of semiconductor patterns and surrounding the first source/drain region. The hole collection layer is disposed between the bit line and a corresponding word line of the plurality of word lines surrounding the corresponding semiconductor pattern. An energy band gap of the first source/drain region is greater than an energy band gap of the hole collection layer.

According to some embodiments of the present disclosure, a method of manufacturing a semiconductor memory device may include: providing a preliminary stacked structure on a substrate, the preliminary stacked structure including a plurality of interlayer insulating layers and a plurality of mold sacrificial layers alternately stacked along a first direction; forming a trench by penetrating the preliminary stacked structure along the first direction and partially patterning the plurality of mold sacrificial layers along a second direction intersecting the first direction; forming an interlayer sacrificial pattern along exposed side surfaces of the patterned mold sacrificial layers interposed among the plurality of interlayer insulating layers inside the trench; forming a semiconductor pattern to be interposed between the formed interlayer sacrificial patterns; partially patterning the interlayer sacrificial pattern along the second direction; forming a gate insulating film on inner walls of the trench defined by a lower surface and an upper surface of each of the plurality of interlayer insulating layers and side surfaces of the patterned interlayer sacrificial pattern; forming a word line on the gate insulating film; forming a first portion of a first source/drain region by partially removing the gate insulating film so as to externally expose a portion of the semiconductor pattern; and forming a second portion of the first source/drain region on a surface of the first portion, wherein the semiconductor pattern may include a channel region surrounded by the word line.

### ADVANTAGEOUS EFFECTS

According to some embodiments of the present disclosure, an energy band gap of a material included in a first source/drain region adjacent to a bit line is formed to be greater than an energy band gap of a material included in a channel region, so that the first source/drain region is configured to collect excess holes that accumulate in the channel region. Accordingly, a floating body effect can be improved.

The effect obtainable from the present disclosure is not limited to that described above. Technical effects not mentioned herein will be clearly understood by those skilled in the art from the description of the present disclosure below.

### BRIEF DESCRIPTION OF THE DRAWINGS

FIG. 1 illustrates a cell array of a semiconductor memory device according to some embodiments of the present disclosure.

FIG. 2 is a plan view illustrating a semiconductor memory device according to some embodiments of the present disclosure.

FIG. 3 is a cross-sectional view illustrating the semiconductor memory device of FIG. 2, taken along line A-A of FIG. 2.

FIG. 4 is a cross-sectional view illustrating the semiconductor memory device of FIG. 2, taken along line B-B of FIG. 2.

FIG. 5 is a cross-sectional view illustrating the semiconductor memory device of FIG. 2, taken along line C-C of FIG. 2.

FIG. 6 is a diagram illustrating a semiconductor memory device according to some embodiments of the present disclosure.

FIG. 7 is a diagram illustrating a semiconductor memory device according to some embodiments of the present disclosure.

FIG. 8 is a diagram illustrating a semiconductor memory device according to some embodiments of the present disclosure.

FIG. 9 is a diagram illustrating a semiconductor memory device according to some embodiments of the present disclosure.

FIG. 10 is a diagram illustrating a semiconductor memory device according to some embodiments of the present disclosure.

FIG. 11 is a diagram illustrating a semiconductor memory device according to some embodiments of the present disclosure.

FIG. 12 is a diagram illustrating a semiconductor memory device according to some embodiments of the present disclosure.

FIG. 13 is a diagram illustrating a semiconductor memory device according to some embodiments of the present disclosure.

FIG. 14 is a diagram illustrating a semiconductor memory device according to some embodiments of the present disclosure.

FIGS. 15, 16, 17, 18, 19, 20, 21, 22 and 23, are intermediate-stage diagrams illustrating a method of manufacturing a semiconductor memory device according to an embodiment of the present disclosure.

### DETAILED DESCRIPTION

Hereinafter, various embodiments of the present disclosure will be described with reference to the drawings. The same reference numerals throughout this specification may refer to identical components.

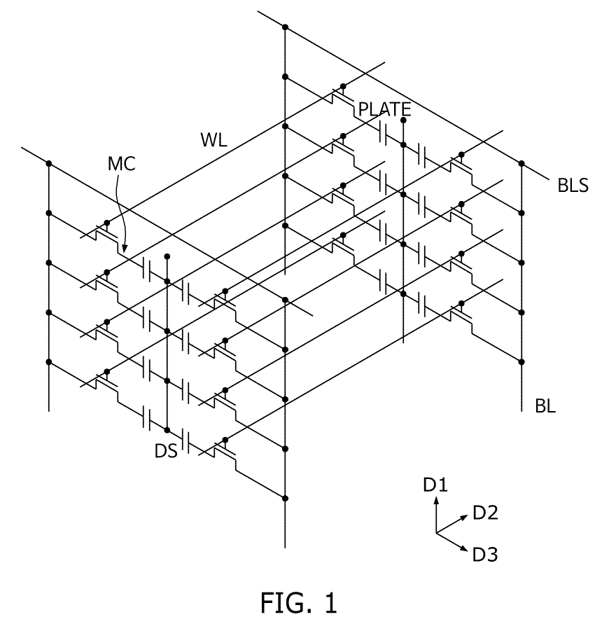

FIG. 1 illustrates a cell array of a semiconductor memory device according to some embodiments of the present disclosure.

Referring to FIG. 1, some embodiments of the semiconductor memory device may include a plurality of memory cells MC arranged in a first direction D1 and a third direction D3. Each memory cell MC may include a data storage element DS and a memory cell transistor arranged in the third direction D3 and connected together.

A plurality of bit lines BL may be conductive patterns (for example, conductive metal lines) extending lengthwise in a direction perpendicular to an upper surface of a substrate (for example, the first direction D1). The plurality of bit lines BL may be arranged in the third direction D3. Adjacent bit lines BL may be spaced apart in the third direction D3.

In some embodiments, some of the plurality of bit lines BL may be interconnected by a bit line strapping line (BLS). For example, the bit line strapping line BLS may interconnect certain bit lines BL arranged along the third direction D3 among the plurality of bit lines BL.

A plurality of word lines WL may be conductive patterns (for example, conductive metal lines) stacked in the first direction D1 on a substrate. Each word line WL may extend lengthwise in a second direction D2. Adjacent word lines WL may be spaced apart in the first direction D1.

The data storage element DS may be commonly connected to a plate electrode PLATE extending in the first direction D1 and the second direction D2. In some embodiments, the plate electrode PLATE arranged along the second direction D2 may be integrally formed.

The data storage element DS and the memory cell transistor arranged in the third direction D3 may be disposed symmetrically with respect to a plane extending in the first direction D1 and the second direction D2 on which the plate electrode PLATE is disposed.

A gate electrode of the memory cell transistor may be connected to the word line WL. A first source/drain of the memory cell transistor may be connected to the bit line BL. A second source/drain of the memory cell transistor may be connected to the data storage element DS. For example, the data storage element DS may be a capacitor structure. The second source/drain of the memory cell transistor may be connected to a storage electrode of the capacitor.

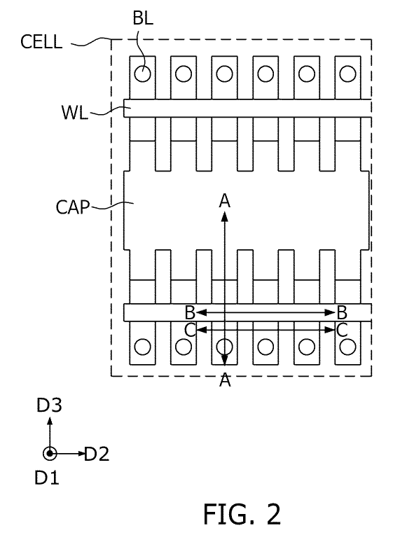

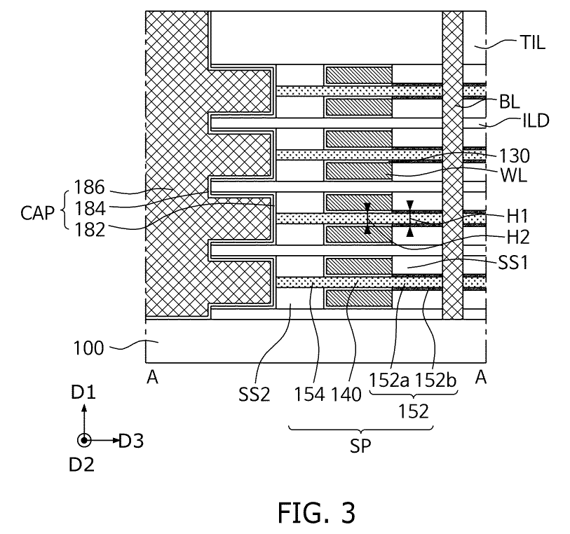

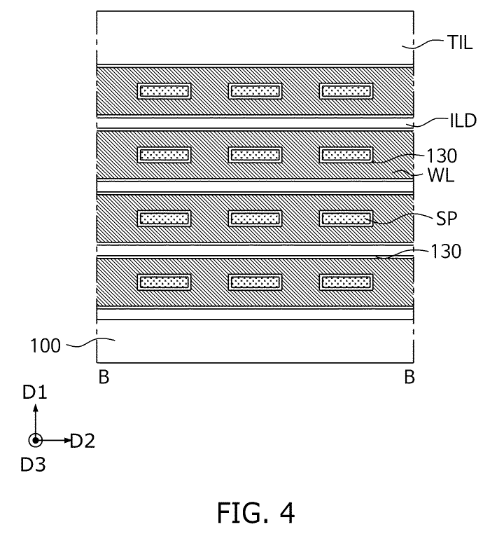

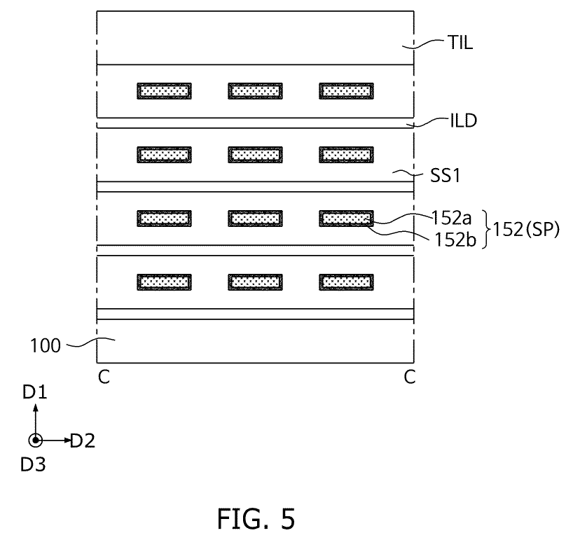

FIG. 2 is a plan view illustrating a semiconductor memory device according to some embodiments of the present disclosure. FIG. 3 is a cross-sectional view illustrating the semiconductor memory device of FIG. 2, taken along line A-A of FIG. 2. FIG. 4 is a cross-sectional view illustrating the semiconductor memory device of FIG. 2, taken along line B-B of FIG. 2. FIG. 5 is a cross-sectional view illustrating the semiconductor memory device of FIG. 2, taken along line C-C of FIG. 2.

Referring to FIGS. 2-5, the semiconductor memory device according to some embodiments of the present disclosure may include a substrate 100 and a plurality of semiconductor patterns SP, a plurality of word lines WL, a bit line BL, and a capacitor structure CAP disposed on the substrate 100.

The substrate 100 may be bulk silicon or silicon-on-insulator (SOI). The substrate 100 may include silicon (Si) or other materials, for example, silicon-germanium, silicon germanium on insulator (SGOI), indium antimonide (InSb), lead tellurium compound (PbTe), indium arsenide (InAs), indium phosphide (InP), gallium arsenide (GaAs), or gallium antimonide (GaSb), but the present disclosure is not limited thereto. For convenience of description, in the following, the substrate 100 is described as including silicon. In addition, on some region of substrate 100, a peripheral circuit and a wiring layer connected to the peripheral circuit may be further formed.

In the present disclosure, a direction perpendicular to a surface (for example, an upper surface) of the substrate 100 may be referred to as the first direction D1. In addition, a direction parallel to a surface (for example, an upper surface) of the substrate 100 may be referred to as the second direction D2 or the third direction D3. The second direction D2 and the third direction D3 may intersect each other (for example, orthogonally).

A plurality of semiconductor patterns SP may be spaced apart in the first direction D1 and stacked on the substrate 100. Each of the plurality of semiconductor patterns SP may have a bar shape with a long axis in the third direction D3. Each of the plurality of semiconductor patterns SP may include a first source/drain region 152 adjacent to the bit line BL, a second source/drain region 154 adjacent to the capacitor structure CAP, and a channel region 140 disposed between the first source/drain region 152 and the second source/drain region 154. The first source/drain region 152 may be connected to the bit line BL, and the second source/drain region 154 may be connected to the capacitor structure CAP.

The semiconductor pattern SP may, for example, include silicon (Si), germanium (Ge), or silicon-germanium (SiGe). In some embodiments, the semiconductor pattern SP may include a two-dimensional semiconductor material (for example, MoS₂ or WSe₂) in the channel.

The first source/drain region 152 and the second source/drain region 154 may have a first conductivity type (for example, an n-type). The channel region 140 may be undoped or may have a second conductivity type (for example, a p-type) different from the first conductivity type. However, the present disclosure is not limited thereto.

According to an embodiment, the first source/drain region 152 may include a first portion 152a extending lengthwise in the third direction D3 from the channel region 140 and a second portion 152b surrounding the first portion 152a. Referring to FIGS. 3 and 5, the second portion 152b may surround an upper surface of the first portion 152a, a lower surface of the first portion 152a, and both side surfaces of the first portion 152a facing in the second direction D2. For example, the second portion 152b may wrap around side surfaces of the first portion 152a.

According to an embodiment, the first portion 152a may include a first material, and the second portion 152b may include a second material. An energy band gap of the first material included in the first portion 152a may be greater than an energy band gap of the second material included in the second portion 152b. For example, the first material may include silicon (Si), and the second material may include silicon-germanium (SiGe). In an embodiment, the material of the first portion 152a may be Si, and the material of the second portion 152b may be SiGe. The second portion 152b may serve as a hole collection layer collecting holes accumulated in the semiconductor pattern which is not biased with a negative voltage. In an embodiment, the second portion 152b may be a part of the first source/drain region 152. The present disclosure is not limited thereto. For example, the second portion 152b may be a layer separately formed on the first portion 152a of the first source/drain region 152. The first portion 152a may serve as a source/drain region, and the second portion 152b may serve as a hole collection layer. In an embodiment, the second portion 152b may not be formed on the second source/drain region 154.

Since the first material and the second material have conduction band and valence band positions that differ from each other, a band offset may be formed between the channel region 140 and the second portion 152b of the first source/drain region 152 in an energy band alignment process. Thus, the second portion 152b of the first source/drain region 152 may function as an excess channel hole collector that collects excess holes accumulated in the channel region 140, thereby improving the floating body effect (FBE). The floating body effect may arise when a transistor’s body (e.g., the semiconductor pattern SP) is electrically isolated (without being biased to a negative voltage when the transistor is an n-type transistor), allowing it to accumulate charge during operation. This modulates the transistor behavior dynamically, and such collection of excess holes by the second portion 152b may reduce body charging of the excess holes in the pattern SP except for the second portion 152b.

According to an embodiment, a first thickness H1 of the first source/drain region 152 may be greater than a second thickness H2 of the channel region 140. In an embodiment, the channel region 140 may have the same thickness as the second source/drain region 154. In the present disclosure, “thickness” may refer to a distance along the first direction D1 between an upper surface and a lower surface of a component. “Thickness” may represent an average distance between an upper surface and a lower surface across the entire surface of the component, or it may represent a distance between the upper surface and the lower surface at a particular point such as a central portion of the component. For example, the distance between an upper surface and a lower surface of the second portion 152b of the first source/drain region 152 may be greater than the distance between an upper surface and a lower surface of the channel region 140.

A plurality of word lines WL may surround each of the plurality of semiconductor patterns SP and may extend lengthwise in the second direction D2. The word lines WL may have a gate-all-around (GAA) structure that completely surrounds the channel region 140.

The word lines WL may include a conductive material. For example, the word lines WL may include at least one of a doped semiconductor material (doped silicon, doped silicon-germanium, doped germanium, etc.), a conductive metal nitride (titanium nitride, tantalum nitride, etc.), a metal (tungsten, titanium, tantalum, etc.), and a metal-semiconductor compound (tungsten silicide, cobalt silicide, titanium silicide), but the present disclosure is not limited thereto.

A gate insulating film 130 may be disposed on the word lines WL. The gate insulating film 130 may be interposed between the word lines WL and adjacent components. Referring to FIGS. 3 and 4, the gate insulating film 130 may be interposed between the channel region 140 and each word line of the word lines WL, between the interlayer insulating layer ILD and the word lines WL, and between a second spacer SS2 and the word lines WL. On the other hand, the gate insulating film 130 may not be interposed between a first spacer SS1 and each word line of the word lines WL. Thus, a first side surface in the third direction D3 of the first spacer SS1 may contact a first side surface in the third direction D3 of each word line WL. The term “contact,” as used herein, refers to a direct connection (i.e., physical touching) unless the context indicates otherwise.]

The gate insulating film 130 may include a high-k insulating film, a silicon oxide film, a silicon nitride film, or a silicon oxynitride film. The high-k insulating film may, for example, include at least one of hafnium oxide, hafnium silicate, lanthanum oxide, zirconium oxide, zirconium silicate, tantalum oxide, titanium oxide, barium strontium titanium oxide, barium titanium oxide, strontium titanium oxide, lithium oxide, aluminum oxide, lead scandium tantalum oxide, and lead zinc niobate.

The interlayer insulating layer ILD may be interposed in spaces between adjacent word lines of the plurality of word lines WL stacked in the first direction D1. The interlayer insulating layer ILD may electrically isolate the adjacent word lines WL from each other. In an embodiment, a portion of the interlayer insulating layer ILD may be disposed between capacitor structures CAP that are adjacent in the first direction D1. For example, the interlayer insulating layer ILD may be interposed in spaces between adjacent first electrodes of a plurality of first electrodes 182 disposed in the first direction D1.

The interlayer insulating layer ILD may include an insulating material. For example, the interlayer insulating layer ILD may be selected from the group consisting of a silicon oxide film, a silicon nitride film, a silicon oxynitride film, a carbon-containing silicon oxide film, a carbon-containing silicon nitride film, and a carbon-containing silicon oxynitride film.

A plurality of bit lines BL may be disposed on the substrate 100. The plurality of bit lines BL may be arranged in the second direction D2. The bit line BL may be disposed on the first side of each of the plurality of semiconductor patterns SP and extend lengthwise in the first direction D1. Each of the plurality of semiconductor patterns SP may be connected to the bit line BL. For example, the bit line BL may be electrically connected to the first source/drain region 152 of each semiconductor pattern SP.

The first spacer SS1 may be interposed between the bit line BL and each word line of the plurality of word lines WL. The first spacer SS1 may be disposed between vertically adjacent interlayer insulating layers ILD, and the first spacer SS1 may surround the first source/drain region 152 of the semiconductor pattern SP. In an embodiment, the first spacer SS1 may be disposed on an upper surface and a lower surface of the second portion 152b of the first source/drain region 152, as well as on both side surfaces of the second portion 152b facing in the second direction D2.

The first spacer SS1 may include an insulating material. For example, the first spacer SS1 may include a high-k insulating material such as a silicon nitride film and a silicon oxynitride film. In an embodiment, the first spacer SS1 may be formed of an oxide-based material (for example, a silicon oxide film (SiO2)) or a multilayer structure based on a nitride material to enhance electrical insulation performance. However, the present disclosure is not limited thereto.

The capacitor structure CAP may be disposed on a second side of each of the plurality of semiconductor patterns SP, the second side facing the first side. The capacitor structure CAP may include a plurality of first electrodes 182, a capacitor dielectric film 184, and a second electrode 186.

The plurality of first electrodes 182 may be disposed on the second side of each of the plurality of semiconductor patterns SP and may be stacked in the first direction D1. Each first electrode of the first electrodes 182 may be interposed between adjacent interlayer insulating layers of the interlayer insulating layers ILD in the first direction D1.

For example, each first electrode 182 may extend in the first direction D1 along a profile of a side surface (for example, a side surface in the third direction D3) of the second source/drain region 154 and along a side surface (for example, a side surface in the third direction D3) of the second spacer SS2 surrounding the second source/drain region 154, and may extend in the third direction D3 along the surface profile of portions of the upper surface and the lower surface of the adjacent interlayer insulating layer ILD.

The first electrode 182 may include at least one of a metal, a metal nitride film, and a metal silicide. For example, the first electrode 182 may include a refractory metal film such as cobalt, titanium, nickel, tungsten, and molybdenum. The first electrode 182 may include a metal nitride film such as titanium nitride, titanium silicon nitride, titanium aluminum nitride, tantalum nitride, tantalum silicon nitride, tantalum aluminum nitride, and tungsten nitride.

The second electrode 186 may be spaced apart from the first electrode 182. The capacitor dielectric film 184 may be disposed between the first electrode 182 and the second electrode 186. The second electrode 186 may extend along the capacitor dielectric film 184. The second electrode 186 may fill an interior space formed along the profile of the capacitor dielectric film 184. The second electrode 186 may extend in the first direction D1. The second electrode 186 may be the plate electrode PLATE described with reference to FIG. 1.

The second electrode 186 may, for example, include at least one of doped silicon, a metal, a metal nitride film, and a metal silicide. In some embodiments, the second electrode 186 may include substantially the same material as the first electrode 182.

The capacitor dielectric film 184 may be interposed between the first electrode 182 and the second electrode 186. The capacitor dielectric film 184 may be disposed along the profile of the first electrode 182 and along a side surface profile in the third direction D3 of the interlayer insulating layer ILD. The capacitor dielectric film 184 may include at least one of a metal oxide such as hafnium oxide, zirconium oxide, aluminum oxide, lanthanum oxide, tantalum oxide, and titanium oxide, and a dielectric material having a perovskite structure such as SrTiO₃ (STO), (Ba,Sr)TiO₃ (BST), BaTiO₃, PZT, and PLZT.

A second spacer SS2 may be interposed between the capacitor structure CAP and each word line of the plurality of word lines WL. The second spacer SS2 may be disposed between vertically adjacent interlayer insulating layers ILD, and the second spacer SS2 may surround the second source/drain region 154 of the semiconductor pattern SP. For example, the second spacer SS2 may be disposed on an upper surface and a lower surface of the second source/drain region 154 and on both side surfaces of the second source/drain region 154 facing in the second direction D2. The second spacer SS2 may include an insulating material. For example, the second spacer SS2 may include the same or a similar material as the first spacer SS1.

An upper insulating layer TIL may cover a stacked structure in which the plurality of word lines WL and the plurality of interlayer insulating layers ILD are alternately stacked with the semiconductor pattern SP interposed therebetween. The capacitor structure CAP and/or the bit line BL may penetrate through the upper insulating layer TIL. The upper insulating layer TIL may include a silicon oxide film, a silicon nitride film, or a silicon oxynitride film, but the present disclosure is not limited thereto.

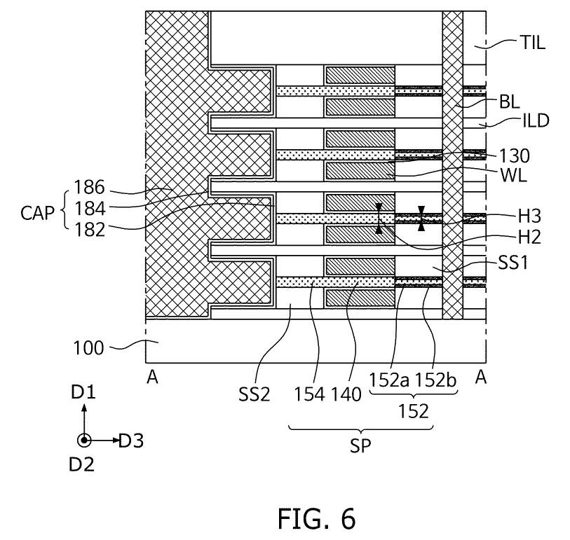

FIGS. 6-9 are diagrams illustrating a semiconductor memory device according to some embodiments of the present disclosure. Each of FIGS. 6-9 may correspond to a cross-sectional view taken along line A-A of FIG. 2. The semiconductor memory device in FIGS. 6-9 may be substantially the same as the semiconductor memory device described with reference to FIGS. 1-5, except for the shape of the first source/drain region 152. Hereinafter, for convenience of description, a focus will be placed on configurations different from those described in FIGS. 1-5.

According to an embodiment, a third thickness H3 of the first portion 152a of the first source/drain region 152 may be less than the second thickness H2 of the channel region 140. Referring to FIG. 6, the distance between the upper surface and the lower surface of the first portion 152a may be less than the distance between the upper surface and the lower surface of the channel region 140. In this case, a thickness of the first source/drain region 152 may be the same as or less than the second thickness H2 of the channel region 140. In an embodiment, the channel region 140 may have the same thickness as the second source/drain region 154. For example, the distance between the upper surface and the lower surface of the second portion 152b of the first source/drain region 152 may be the same as or less than the distance between the upper surface and the lower surface of the channel region 140.

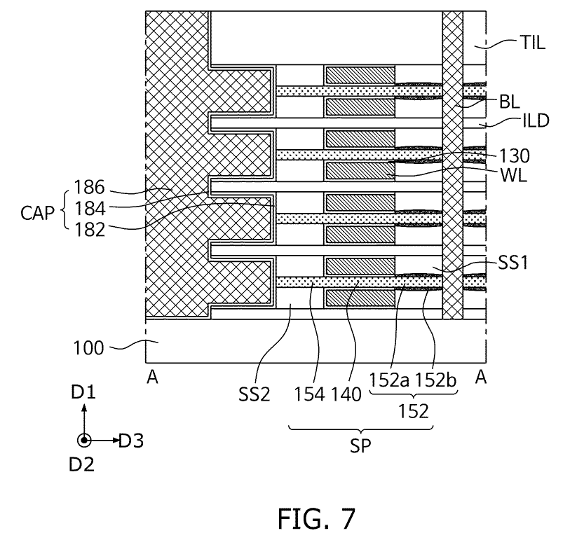

According to an embodiment, a surface of the second portion 152b of the first source/drain region 152 may have a convex shape. Referring to FIG. 7, the surface of the second portion 152b may be outwardly convex so that a central portion is thicker than an end portion.

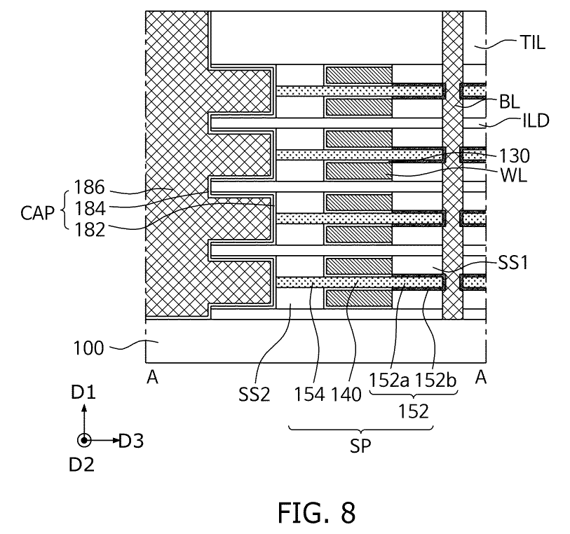

According to an embodiment, the second portion 152b of the first source/drain region 152 may completely surround entire surface of the first portion 152a except for the surface through which the first portion 152a is connected to the channel region 140. Referring to FIG. 8, the second portion 152b of the first source/drain region 152 may be further disposed between the first portion 152a and the bit line BL. For example, the second portion 152b may be disposed on an upper surface of the first portion 152a, a lower surface of the first portion 152a, and both side surfaces of the first portion 152a facing in the second direction D2, and on a first surface of the first portion 152a adjacent to the bit line BL in the third direction D3.

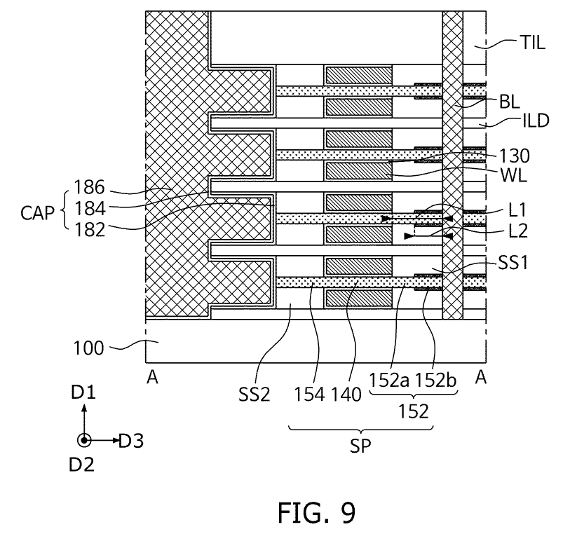

According to an embodiment, the second portion 152b of the first source/drain region 152 may surround portions of each of the upper surface of the first portion 152a, the lower surface of the first portion 152a, and both side surfaces of the first portion 152a facing in the second direction D2. Referring to FIG. 9, a first length L1 of the first portion 152a in the third direction D3 may be greater than a second length L2 of the second portion 152b in the third direction D3. The second portion 152b may be spaced apart from the word line WL in the third direction D3.

The exemplary embodiments described with reference to FIGS. 6-9 are not mutually exclusive. For example, some exemplary embodiments may include one or more features referenced in each of FIGS. 6-9 combined with one or more other features referenced in different figures.

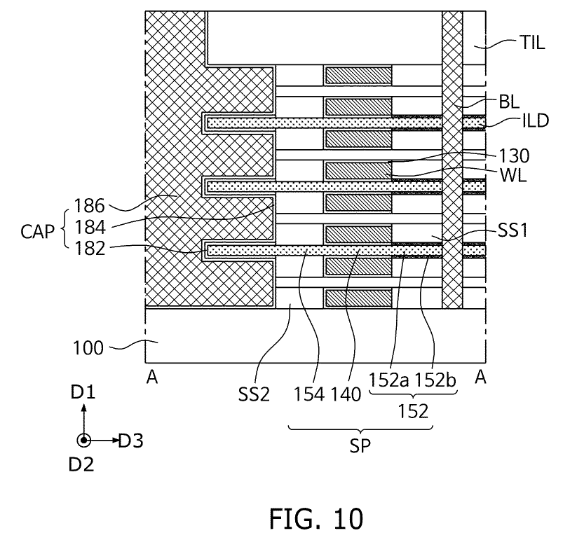

FIG. 10 is a diagram illustrating a semiconductor memory device according to some embodiments of the present disclosure. FIG. 10 may correspond to a cross-sectional view taken along line A-A of FIG. 2. The semiconductor memory device in FIG. 10 may be substantially the same as the semiconductor memory device described with reference to FIGS. 1-9, except for the shape of the capacitor structure CAP. Hereinafter, for convenience of description, a focus will be placed on configurations different from those described in FIGS. 1-9.

According to an embodiment, each first electrode 182 may surround a portion of the semiconductor pattern SP. Referring to FIG. 10, the first electrode 182 may be disposed on the second side of the semiconductor pattern SP that is connected to the capacitor structure CAP, and a portion of each of an upper surface and a lower surface of the semiconductor pattern SP that are connected to the second side. The first electrode 182 may not contact the interlayer insulating layer ILD. For example, the first electrode 182 may be separated from the interlayer insulating layer ILD.

The capacitor dielectric film 184 may be interposed between the first electrode 182 and the second electrode 186. The capacitor dielectric film 184 may be disposed along the profile of the first electrode 182 and along the side surface profile of the interlayer insulating layer ILD in the first direction D1.

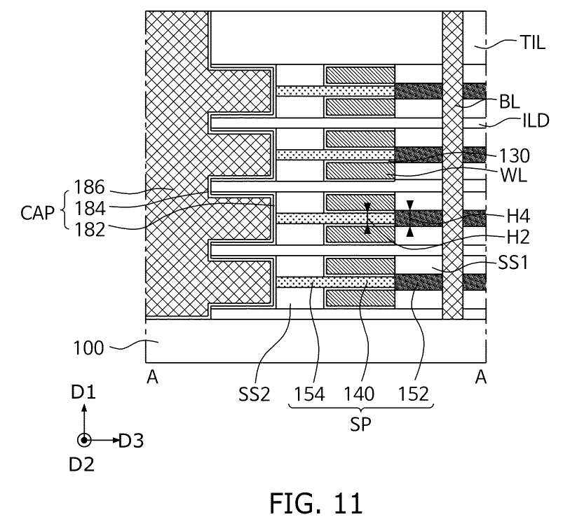

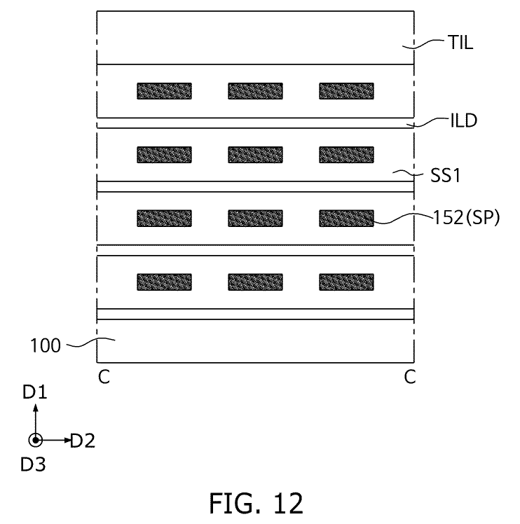

FIGS. 11-14 are diagrams illustrating a semiconductor memory device according to some embodiments of the present disclosure. FIGS. 11, 13, and 14 may each correspond to a cross-sectional view taken along line A-A of FIG. 2, and FIG. 12 may correspond to a cross-sectional view taken along line C-C of FIG. 2. The semiconductor memory device in FIGS. 11-14 may be substantially the same as the semiconductor memory device described with reference to FIGS. 1-10, except for the shape of the first source/drain region 152. Hereinafter, for convenience of description, a focus will be placed on configurations different from those described in FIGS. 1-10.

Referring to FIGS. 11-14, each of the plurality of semiconductor patterns SP may include a first source/drain region 152 adjacent to the bit line BL, a second source/drain region 154 adjacent to the capacitor structure CAP, and a channel region 140 disposed between the first source/drain region 152 and the second source/drain region 154.

According to an embodiment, the first source/drain region 152 and the channel region 140 may include different materials. For example, the channel region 140 may include a first material, and the first source/drain region 152 may include a second material. An energy band gap of the first material included in the channel region 140 may be greater than an energy band gap of the second material included in the first source/drain region 152. For example, the first material may include silicon (Si), and the second material may include silicon-germanium (SiGe). However, the present disclosure is not limited thereto. In an embodiment, a material of the first source/drain region 152 may be different form a material of the channel region 140. In an embodiment, a material of the first source/drain region 152 may be different from a material of the second source/drain region 154, and the first and second source/drain regions 152 and 154 may be doped with the same dopant.

According to an embodiment, a fourth thickness H4 of the first source/drain region 152 may be greater than the second thickness H2 of the channel region 140. Referring to FIG. 11, the distance between the upper surface and the lower surface of the first source/drain region 152 may be greater than the distance between the upper surface and the lower surface of the channel region 140.

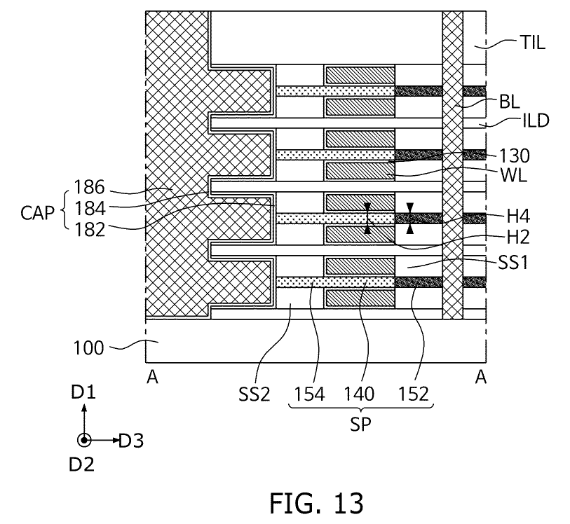

According to an embodiment, the fourth thickness H4 of the first source/drain region 152 may be equal to the second thickness H2 of the channel region 140. In an embodiment, the channel region 140 may have the same thickness as the second source/drain region 154. Referring to FIG. 13, the distance between the upper surface and the lower surface of the first source/drain region 152 may be the same as or substantially the same as the distance between the upper surface and the lower surface of the channel region 140.

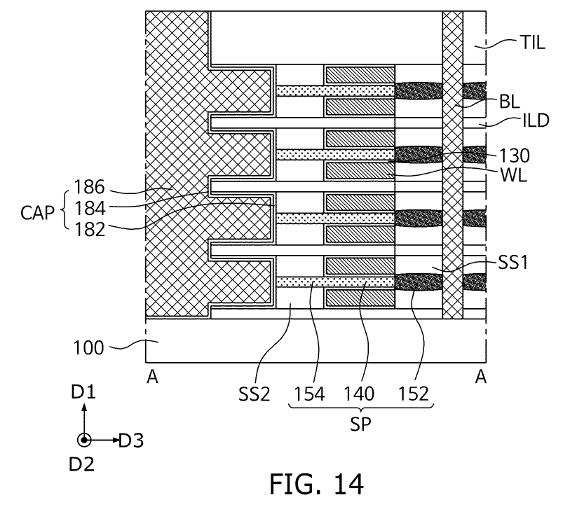

According to an embodiment, a surface of the first source/drain region 152 may have a convex shape. Referring to FIG. 14, the surface of the first source/drain region 152 may be outwardly convex so that a central portion is thicker than an end portion.

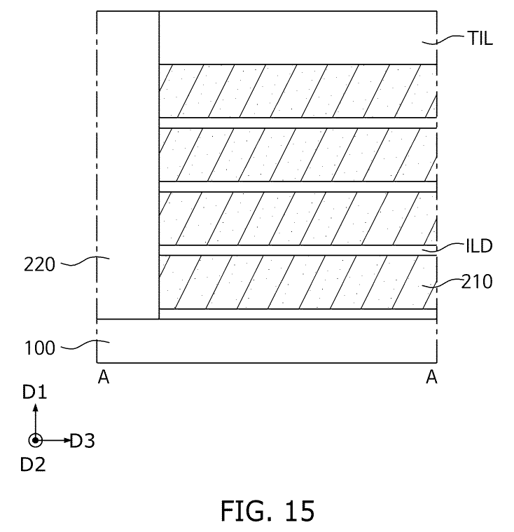

FIGS. 15-23 are intermediate-stage diagrams illustrating a method of manufacturing a semiconductor memory device according to an embodiment of the present disclosure. FIGS. 15-23 may correspond to a cross-sectional view taken along line A-A of FIG. 2.

Referring to FIG. 15, a preliminary stacked structure in which a plurality of interlayer insulating layers ILD and a plurality of mold sacrificial layers 210 are alternately stacked in a first direction D1 may be provided on the substrate 100. An upper insulating layer TIL may be formed on the top surface of the preliminary stacked structure, and a sacrificial pillar pattern 220 penetrating the preliminary stacked structure and the upper insulating layer TIL in the first direction D1 may be formed. The mold sacrificial layer 210 and the sacrificial pillar pattern 220 may be formed of an insulating material having etch selectivity relative to the interlayer insulating layer ILD. For example, the mold sacrificial layer 210 and the sacrificial pillar pattern 220 may be silicon oxide. However, the present disclosure is not limited thereto.

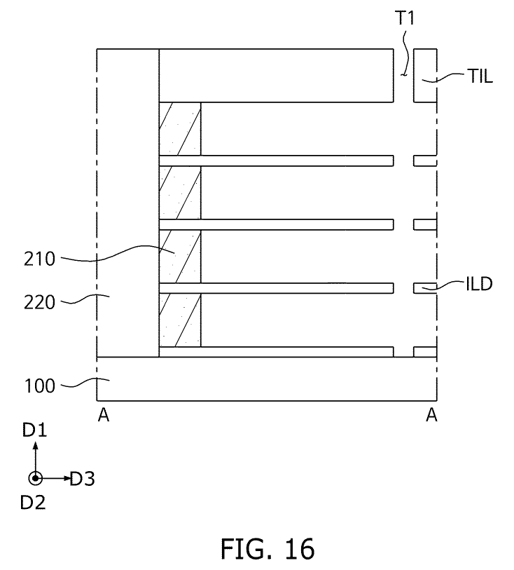

Referring to FIG. 16, a first trench T1 may be formed by penetrating the preliminary stacked structure and the upper insulating layer TIL in the first direction D1, and partially patterning the mold sacrificial layer 210 in the third direction D3.

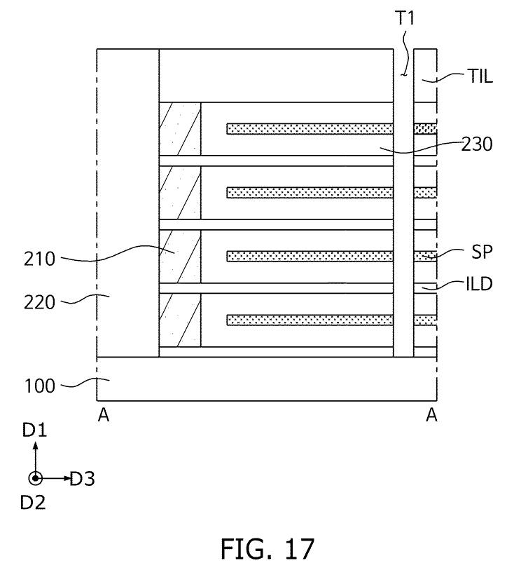

Referring to FIG. 17, an interlayer sacrificial pattern may be formed along exposed side surfaces of the patterned mold sacrificial layer 210 interposed among the plurality of interlayer insulating layers ILD inside the first trench T1. For example, the mold sacrificial layer 210 may be patterned in the third direction D3 to form interior spaces, and an interlayer sacrificial pattern 230 may be formed along the surfaces of each interior space. The interlayer sacrificial pattern 230 may be formed along the upper surface and the lower surface of the interlayer insulating layer ILD and along the exposed side surfaces of the mold sacrificial layer 210.

Subsequently, after forming the interlayer sacrificial pattern 230, a semiconductor pattern SP may be filled in the interior spaces. The semiconductor pattern SP may be formed in a space between the formed interlayer sacrificial patterns 230.

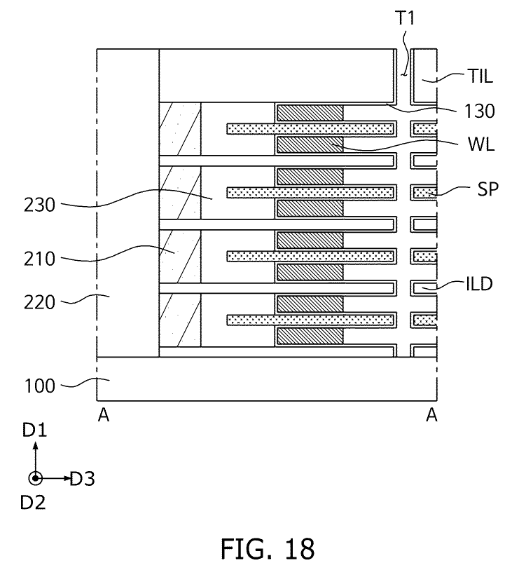

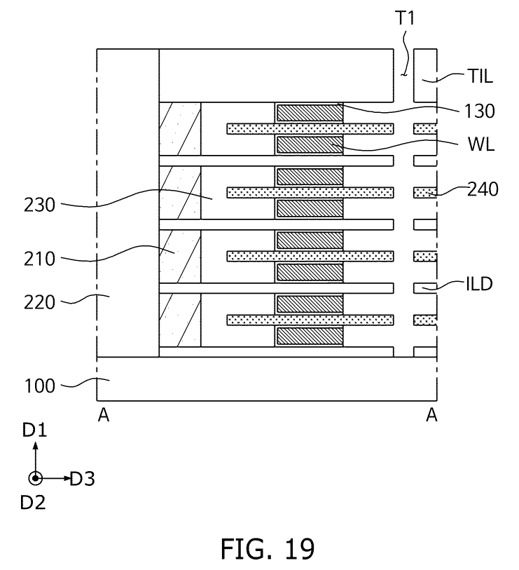

Referring to FIGS. 18 and 19, the interlayer sacrificial pattern 230 may be partially patterned in the third direction D3. The patterned interlayer sacrificial pattern 230 may function as the second spacer that surrounds the second source/drain region (for example, the second source/drain region 154 in FIG. 3) of the semiconductor pattern SP. Thereafter, the gate insulating film 130 may be formed on inner walls of the first trench T1, which are defined by the lower surface and the upper surface of each of the plurality of interlayer insulating layers ILD and the side surfaces of the patterned interlayer sacrificial pattern 230. Then, a conductive material may be filled on the gate insulating film 130 formed between the interlayer insulating layer ILD and the semiconductor pattern SP, and between the uppermost semiconductor pattern SP and the upper insulating layer TIL, thereby forming the word line WL.

Subsequently, as the gate insulating film 130 formed on the inner wall of the first trench T1 is partially removed, a portion of the semiconductor pattern SP and a first side surface in the third direction D3 of each word line WL may be externally exposed. The exposed portion of the semiconductor pattern SP may function as the first source/drain region.

According to some embodiments of the method of manufacturing the semiconductor memory device described with reference to FIGS. 11-14, the gate insulating film 130 formed on the inner wall of the first trench T1 may be partially removed, the exposed portion of the semiconductor pattern SP may be removed together, and a first side surface of the semiconductor pattern SP aligned with a first side surface of the word line WL may be externally exposed.

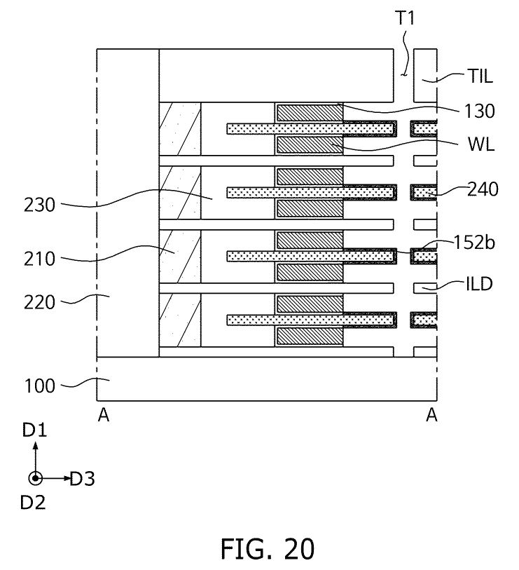

Referring to FIG. 20, a second portion 152b of the first source/drain region may be formed on the surface of the exposed semiconductor pattern SP. The second portion 152b of the first source/drain region may be formed by an epitaxial growth method.

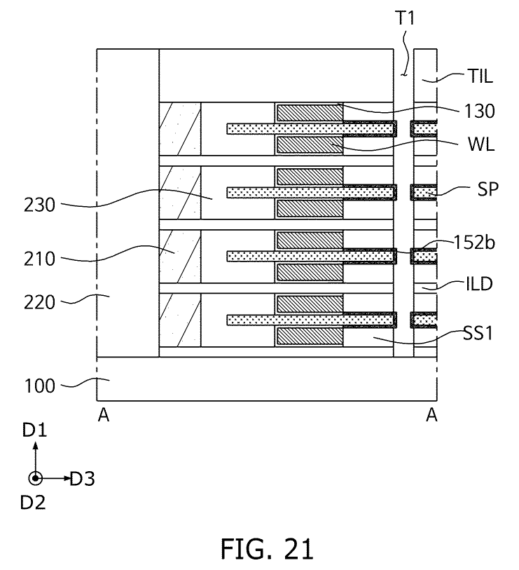

Referring to FIG. 21, a first spacer SS1 that surrounds the second portion 152b of the first source/drain region may be formed. During a time when the first spacer SS1 is formed, a portion of the second portion 152b formed on the side surface of the semiconductor pattern SP in the third direction D3 may be partially removed. However, the scope of the present disclosure is not limited thereto.

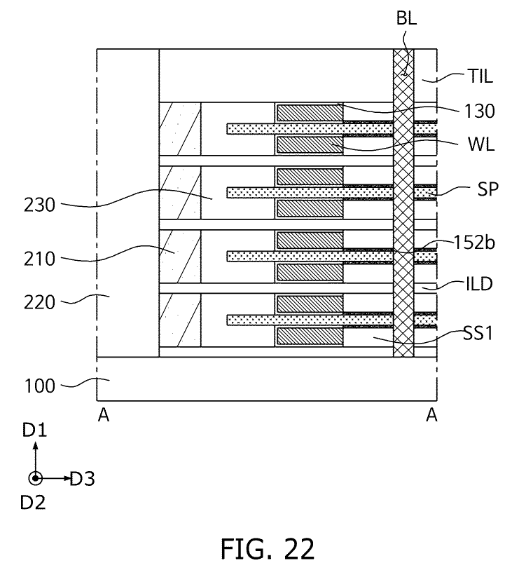

Referring to FIG. 22, a conductive material may fill inside the first trench T1 so that a bit line BL extending lengthwise in the first direction D1 is formed.

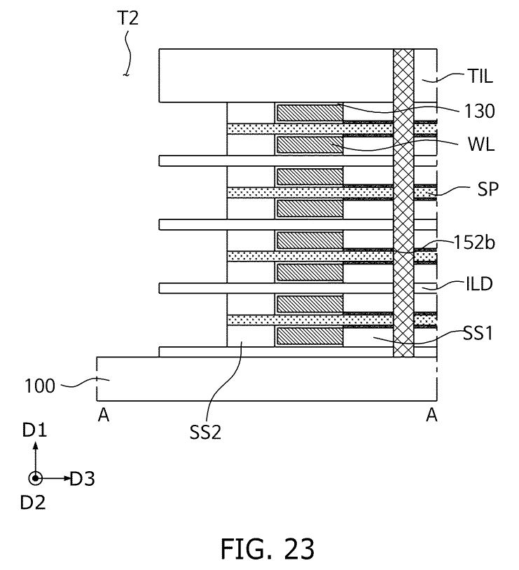

Referring to FIG. 23, portions of the sacrificial pillar pattern 220 and the patterned mold sacrificial layer 210 may be removed and then the patterned interlayer sacrificial pattern 230 may be partially removed to form a second trench T2. The remaining portions of the patterned interlayer sacrificial pattern 230 may correspond to the second spacers SS2. A capacitor structure (for example, the capacitor structure CAP of FIG. 3) may be formed in the second trench T2. Through this or a similar manufacturing method, the semiconductor memory device described with reference to FIGS. 1-14 may be provided.

Although the present disclosure has been described above with reference to limited embodiments and drawings, the present disclosure is not limited thereby, and it is of course possible for those skilled in the art to make various modifications and variations within the technical spirit of the present disclosure and within the equivalent scope of the claims provided below.

The exemplary embodiments are not defined as mutually exclusive. For example, certain exemplary embodiments may include one or more features referenced in any one figure, and may also include, at the same time, one or more other features referenced in other figures.

What is claimed is:

1. A semiconductor memory device comprising:
a substrate;
a plurality of semiconductor patterns stacked on the substrate and being spaced apart from each other in a first direction perpendicular to an upper surface of the substrate;
a plurality of word lines surrounding the plurality of semiconductor patterns, respectively, and extending lengthwise in a second direction parallel to the upper surface of the substrate and intersecting the first direction;
a bit line on a first side of each semiconductor pattern of the plurality of semiconductor patterns and extending lengthwise in the first direction; and
a capacitor structure on a second side of each semiconductor pattern of the plurality of semiconductor patterns, the second side being opposite to the first side in a third direction parallel to the upper surface of the substrate and intersecting the first direction and the second direction, and each semiconductor pattern of the plurality of semiconductor patterns extending lengthwise in the third direction,
wherein each semiconductor pattern of the plurality of semiconductor patterns comprises:
a first source/drain region adjacent to the bit line,
a second source/drain region adjacent to the capacitor structure, and
a channel region between the first source/drain region and the second source/drain region,
wherein the first source/drain region, the channel region, and the second source/drain region are arranged in the third direction, and
wherein the first source/drain region comprises:
a first portion extending in the third direction from the channel region, and
a second portion surrounding the first portion.

2. The semiconductor memory device according to claim 1,
wherein an energy band gap of a first material included in the first portion is greater than an energy band gap of a second material included in the second portion.

3. The semiconductor memory device according to claim 1,
wherein a thickness of the first source/drain region is greater than a thickness of each of the channel region and the second source/drain region.

4. The semiconductor memory device according to claim 1,
wherein a thickness of the first portion is less than a thickness of each of the second source/drain region and the channel region, and
wherein a material of the first portion is the same as a material of the channel region.

5. The semiconductor memory device according to claim 1,
wherein a surface of the second portion is outwardly convex such that a central portion of the second portion is thicker than an end portion of the second portion.

6. The semiconductor memory device according to claim 1,
wherein the second portion is on an upper surface of the first portion, on a lower surface of the first portion, on both side surfaces of the first portion facing to each other in the second direction, and on a first surface of the first portion adjacent to the bit line in the third direction.

7. The semiconductor memory device according to claim 1,
wherein a length of the first portion in the third direction is greater than a length of the second portion in the third direction.

8. The semiconductor memory device according to claim 1,
wherein the second portion is spaced apart from a corresponding word line of the plurality of word lines in the third direction.

9. The semiconductor memory device according to claim 1, further comprising:
a first spacer surrounding the first source/drain region and disposed between the bit line and a corresponding word line of the plurality of word lines.

10. The semiconductor memory device according to claim 9,
wherein the first spacer and the corresponding word line are arranged in the third direction, and wherein the first spacer contacts the corresponding word line.

11. The semiconductor memory device according to claim 1,
wherein the capacitor structure comprises:
a first electrode connected to a second side of a corresponding semiconductor pattern of the plurality of semiconductor patterns that is adjacent to the first electrode in the third direction;
a second electrode spaced apart from the first electrode; and
a capacitor dielectric film interposed between the first electrode and the second electrode.

12. The semiconductor memory device according to claim 11, further comprising:
a second spacer surrounding the second source/drain region and disposed between the capacitor structure and a corresponding word line of the plurality of word lines,
wherein the first electrode extends in the first direction along a side surface of the second source/drain region and along a side surface of the second spacer.

13. The semiconductor memory device according to claim 11,
wherein the first electrode is on the second side of the corresponding semiconductor pattern, on a portion of an upper surface of the corresponding semiconductor pattern connected to the second side, and on a portion of a lower surface of the corresponding semiconductor pattern.

14. A semiconductor memory device comprising:
a substrate;
a plurality of semiconductor patterns stacked on the substrate in a first direction perpendicular to an upper surface of the substrate;
a plurality of word lines surrounding the plurality of semiconductor patterns, respectively, and extending in a second direction parallel to the upper surface of the substrate and intersecting the first direction;
a bit line on a first side of each semiconductor pattern of the plurality of semiconductor patterns and extending lengthwise in the first direction; and
a capacitor structure on a second side of each semiconductor pattern of the plurality of semiconductor patterns, the second side being opposite to the first side in a third direction parallel to the upper surface of the substrate and intersecting the first direction and the second direction, and each semiconductor pattern of the plurality of semiconductor patterns extending lengthwise in the third direction,
wherein each semiconductor pattern of the plurality of semiconductor patterns comprises:
a first source/drain region adjacent to the bit line,
a second source/drain region adjacent to the capacitor structure, and
a channel region between the first source/drain region and the second source/drain region, and
wherein a material of the first source/drain region is different from a material of each of the channel region and the second source/drain region.

15. The semiconductor memory device according to claim 14,
wherein an energy band gap of a first material included in the channel region is greater than an energy band gap of a second material included in the first source/drain region.

16. The semiconductor memory device according to claim 14,
wherein a thickness of the first source/drain region is greater than or equal to a thickness of each of the channel region and the second source/drain region.

17. The semiconductor memory device according to claim 14,
wherein a surface of the first source/drain region is outwardly convex such that a central portion of the first source/drain region is thicker than an end portion of the first source/drain region.

18. The semiconductor memory device according to claim 14,
wherein the capacitor structure comprises:
a first electrode connected to a second side of a corresponding semiconductor pattern of the plurality of semiconductor patterns that is adjacent to the first electrode in the third direction;
a second electrode spaced apart from the first electrode; and
a capacitor dielectric film interposed between the first electrode and the second electrode.

19. The semiconductor memory device according to claim 18,
wherein the first electrode is further on a portion of an upper surface of the corresponding semiconductor pattern connected to the second side and on a portion of a lower surface of the corresponding semiconductor pattern.

20. A semiconductor memory device comprising:
a substrate;
a plurality of semiconductor patterns stacked on the substrate in a first direction perpendicular to an upper surface of the substrate;
a plurality of word lines surrounding the plurality of semiconductor patterns, respectively, and extending lengthwise in a second direction parallel to the upper surface of the substrate and intersecting the first direction;
an interlayer insulating layer interposed between two adjacent word lines of the plurality of word lines;
a bit line on a first side of each semiconductor pattern of the plurality of semiconductor patterns and extending lengthwise in the first direction;
a capacitor structure on a second side of each semiconductor pattern of the plurality of semiconductor patterns, the second side being opposite to the first side in a third direction parallel to the upper surface of the substrate and intersecting the first direction and the second direction,
wherein each semiconductor pattern of the plurality of semiconductor patterns comprises:
a first source/drain region adjacent to the bit line,
a second source/drain region adjacent to the capacitor structure, and
a channel region between the first source/drain region and the second source/drain region, and
wherein the first source/drain region extends in the third direction from the channel region; and
a hole collection layer configured to collect holes in a corresponding semiconductor pattern of the plurality of semiconductor patterns and surrounding the first source/drain region,
wherein the hole collection layer is disposed between the bit line and a corresponding word line of the plurality of word lines surrounding the corresponding semiconductor pattern, and
wherein an energy band gap of the first source/drain region is greater than an energy band gap of the hole collection layer.
